(19) United States
(12) Patent Application Publication
(10) Pub. No.: US 2012/0043640 A1
(43) Pub. Date: Feb. 23, 2012

(54) MATERIAL HAVING A LOW DIELECTRIC KONSTANT AND METHOD OF MAKING THE SAME

(76) Inventors: Sembukuttiarachilage Ravi Pradip Silva, Surrey (GB); José Virgilio Anguita Rodriguez Estefania, Hook Hampshire (GB)

(21) Appl. No.: 13/264,885

(22) PCT Filed: Apr. 16, 2010
(86) PCT No.: PCT/GB2010/000772

§ 371 Date: Oct. 17, 2011

(30) Foreign Application Priority Data
Apr. 17, 2009 (GB) 0906680.4

(51) Int. Cl. H01L 29/06; B29C 59/14; C08F 10/06; B29C 59/12; C08F 2/34; C08F 2/48

(52) U.S. Cl. 257/506; 526/351; 522/184; 204/168; 257/E29.02

(57) ABSTRACT

There is disclosed a method for producing a highly cross-linked polypropylene material by plasma polymerisation of a carbon containing gas, not specifically propylene, exhibiting low relative permittivity, high thermal stability and enhanced mechanical properties, said method and material being suitable for application not limited to interlayer dielectric deposition in microchip fabrication.

### FIELD OF THE INVENTION

The present invention relates to a highly cross-linked polypropylene-like material and to a method of producing such a material. The preferred embodiments relate to a highly cross-linked polypropylene material which has a controllable dielectric constant (k value), which can be tuned to a low relative permittivity, for instance compared to silicon dioxide, and which can exhibit mechanical properties approaching those of ceramics. The highly cross-linked polypropylene material is suitable for use in microelectronic fabrication, as well as for wider application as a protective, lubricating and load bearing coating and for many other uses. These uses include opto-electronic applications where these tunable dielectric properties can be exploited.

### BACKGROUND TO THE INVENTION

The dielectric constant of a material represents the energy stored when a potential is applied across the material. It is defined relative to the energy stored in a vacuum and is sometimes referred to as the relative static permittivity of a material. The dielectric constant is often represented by the symbols ∈ᵣ or κ, but in the field of microchip manufacture is normally indicated by the letter k, and this latter nomenclature is adopted in this document, referring to the dielectric constant as a “k value”.

In microchips, dielectric layers are provided between conducting parts (such as conducting lines and transistors). As the drive to miniaturise devices continues, dielectric layers are thinner and conducting parts are closer together. At higher operating frequencies, capacitive cross-talk between the various circuit elements limits switching frequencies and further generates heat that limits thermal performance.

The capacitive charge stored across a dielectric layer is directly proportional to the dielectric constant (k value) of the material from which the dielectric layer is formed. As such, materials having a lower dielectric constant enable faster switching frequencies, and reduce heat loss and crosstalk.

Conventionally, silicon dioxide (SiO₂) and silicon nitride (Si₃N₄) have been used to form dielectric layers in silicon microchips. These materials are well suited to the manufacturing processes used for semiconductor microchips and provide a low-cost and reliable solution. The intrinsic k values of SiO₂ and Si₃N₄, however, are considered too high and generally have to be lowered by depositing them with a porous structure or doping them with lower k-value materials to achieve a lower effective k value.

Various attempts have been made to develop new dielectric materials that are suitable for use in semiconductor microchips and have a lower k value than SiO₂ and Si₃N₄ based films. In broad terms, two categories of materials have been investigated: those that produce “hard” layers, and those that produce “soft” layers.

Hard layer materials include ceramic materials that are relatively rigid, such as doped silicon dioxide, silicon nitride, alumina, titania and hafnium dioxide. Layers of these materials may be fabricated through chemical vapour deposition (CVD), particularly plasma-enhanced chemical vapour deposition (PECVD), and sputtering, amongst other techniques.

Advantages of hard layer materials include their chemical consistency, relatively high breakdown voltage and low (thermal) loss, even at high frequencies. The fabrication techniques used for hard layer materials are also highly repeatable and scalable to current microelectronic materials such as silicon.

However, hard layer materials suffer from a number of disadvantages. For example, it is difficult to fabricate a film of such materials having a thickness above a certain threshold (typically around 1 μm) because interface forces between the hard layer material and the substrate on which it is formed can cause delamination. These interface forces are proportional to the thickness of the hard layer material and are inherent to commonly used PECVD deposition methods. In particular, the interface between a hard layer material and the substrate on which it is formed is subjected to stress caused by coherency strain between the two layers, surface energy differences, dislocation energy strain and differing rates of thermal expansion of the hard layer material and the substrate. The manufacturing process itself can result in the creation or dominance of thermal stresses and as a result delamination of the hard layer material can be a significant issue. This problem can be mitigated by matching the thermal expansion coefficients of the hard layer material and the substrate, but this severely restricts the selection of materials.

Soft layer materials do not suffer from these disadvantages due to their inherent flexibility. Examples of such soft layer materials include spin-on glass and spin-on polymers, such as polyamide.

Unfortunately, spin-on polymers typically have relatively poor thermal stability. In order to improve this characteristic it is often necessary to cure the polymer through the application of, for example, heat or radiation. A typical curing process involves baking the polymer at a temperature typically below 500° C. for a time period of seconds to hours depending on the type of polymer. This curing process often produces undesirable by-products and adds processing steps and time delays to the manufacturing process.

Spin-on processes use solvents to create thin-films of polymers. The solvents are intended to evaporate during the process, but some quantity of solvent typically remains in the material even after curing, resulting in material inconsistencies and impurities. These impurities present in spin-on polymers limit their application as a dielectric material in microchip manufacture, despite the fact that it is possible to achieve a relatively low k value. In particular, it has been found that the water and solvent molecules in the film absorb radio frequency energy, resulting in power loss and film degradation during operation.

In Biomaterials, volume 7(2), March 1986, at pages 155 to 157 in the article “Characterisation of plasma polymerised polypropylene coatings”, R. Sipehia and A. S. Chawla disclose a method for forming a plasma polymerised polypropylene film on a substrate in which a propylene monomer is polymerised at low pressure in a radio frequency plasma reactor. The formation of polypropylene via a polymerisation of propylene is expected due to the energy coupling from the plasma.

Other prior art methods in this general field are disclosed in U.S. Pat. No. 4,632,844, U.S. Pat. No. 4,312,575 and U.S. Pat. No. 5,000,831.

### SUMMARY OF THE INVENTION

The present invention seeks to provide a method of producing a highly cross-linked polypropylene-like material and devices such as electronic circuits and opto-electronic circuits which incorporate such a material.

According to an aspect of the present invention, there is provided a method of producing a highly cross-linked polypropylene material including the steps of: providing a reaction chamber; selecting one or more carbon containing gases from a plurality of carbon containing gases; feeding said one or more selected carbon containing gases into said chamber; striking a plasma in said chamber, said plasma causing said gas or gases to dissociate into a phase including methyl radicals; causing said dissociated phase to nucleate and thereby to create highly cross-linked polypropylene material, preferably under high UV radiation.

Advantageously, the polypropylene material comprises a plurality of polymer chains of repeating structural units, with an average of at least one cross-link per six structural units and/or a plurality of cross-links across adjacent polymer chains.

The polypropylene material made by this method, it has been found, exhibits significantly improved characteristics compared to conventional polypropylene, including a very low dielectric constant, good structural characteristics and a high melting point, with enhanced mechanical stability. This makes the material suitable in a wide variety of applications, including as a dielectric or insulating layer for integrated, electronic or opto-electronic circuits. It is also suitable is a great many other applications, such as to provide a protective, lubricating, load-bearing and/or heat resistant coating.

As is explained below, it is believed that the material produced by the method is polypropylene-like. The material exhibits the properties of polypropylene, although has a high incidence of three dimensional cross-linking and has substantially improved characteristics compared to conventional polypropylene. The material is thus referred to herein as polypropylene material, although it is to be understood that this definition encompasses polymer materials formed by the taught method and having the characteristics disclosed herein.

It is preferred that the one or more selected carbon containing gases are selected from a group of gases or vapours including acetylene, acetone, ethylene, ethanol, methane and propylene. Most preferably, a combination of acetylene and acetone is used. In other embodiments, acetylene or acetone alone or a mixture of acetylene or acetone and any other gas may be used.

In this regard, it has been discovered that it is possible to produce the highly three dimensionally cross-linked polypropylene material without having to use propylene as a starting material. It is possible to use other carbon containing gases or vapours. In other words, the method may use one or more of a selection of carbon containing gases which does not include propylene or propene.

The generation of the polypropylene material from any of a variety of carbon containing gases, it has been found, is possible as a result of the dissociation, by means of the striking of the plasma, of the carbon containing input gas into a phase which includes methyl radicals. The method provides for those methyl radicals to fuse with CH chain molecules and to form the highly cross-linked polypropylene material. The provision of UV radiation in the process promotes and enhances the three dimensional cross-linking.

This feature has the benefit of allowing a greater variety of input materials into the process, thus being able to chose input materials in dependence upon the characteristics desired for the process and of the end product.

The input gases may include vapours, such as acetone. It is thus to be understood that references to gases herein encompass also vapours.

Preferably, the plasma has an ultraviolet radiation component, which enhances the production of cross-links in the polypropylene material. This ultraviolet radiation component advantageously has the effect of UV curing the polypropylene material during its synthesis.

In a practical implementation, the method includes the step of providing in the chamber first and second electrical electrodes, wherein the nucleation step includes applying a potential difference across the first and second electrodes.

In one embodiment, the method provides a substrate disposed on one of the first and second electrodes. The nucleation step includes applying a potential difference across the first and second electrodes so as to cause the nucleated material to deposit on the electrode and thereby to cause a layer of highly cross-linked polypropylene material to form on the substrate.

Thus, in this embodiment, the polypropylene material is formed directly on a substrate, which typically may be the surface of a device. The substrate may be a part of an electrical or electronic circuit, in which the highly cross-linked polypropylene material provides an electrically insulating layer on the substrate. In other words, this feature can form directly on an electronic device a dielectric layer, which layer exhibits the particularly advantageous characteristics taught herein.

In another embodiment, the polypropylene material can be nucleated in the plasma phase, that is in the form of particles or flakes, which could be described as being similar to growing like “snow”. In this embodiment, the method advantageously includes the step of collecting the polypropylene material and subsequently depositing the material on a substrate or device. This could be by suspending or dissolving the polypropylene material in a solution. The suspended or dissolved material can then be deposited on a substrate by spray coating, spin-on, electrostatic coating or by any other suitable method.

Preferably, the method includes the step of providing in the chamber a carrier gas which includes at least one supplementary gas. The supplementary gas advantageously includes one or more of: hydrogen, nitrogen, helium, argon, xenon or other noble gas. The supplementary gas can promote enhanced dissociation of the gaseous components within the plasma, thereby to produce highly cross-linked polypropylene material in layer (e.g. thin film), flake or particle form. The supplementary gas can also exhibit a high ionisation potential relative to the carbon containing gas or gases selected for dissociation. In other words, the one or more supplementary gases can assist in ensuring that the carbon containing gas can be ionised at relatively low energies, while increasing the overall plasma energy and the relative number of ionised species in the plasma that take part in the growth of the polymer layer.

It is preferred that the material is also annealed. It has been discovered that annealing can change or reduce the dielectric constant of the polypropylene material.

In practice, it is preferred that the annealing step is carried out in a vacuum or controlled gas environment which uses, for example, one or a composition of inert gases.

Advantageously, the method includes the step of providing additional heating in the chamber by non-plasma means during the plasma nucleation or synthesis step.

A practical embodiment includes the following steps: providing a substrate in the chamber, wherein the said substrate is in contact with an electrode; striking a plasma in the chamber by applying a voltage to a counter electrode inside the chamber, thereby causing a layer of material to form on the substrate; wherein the plasma has an ultra violet radiation component which enhances the cross-linking of the polymer in three dimensions to give mechanical integrity and thermal stability to the material formed.

According to another aspect of the present invention, there is provided a highly cross-linked polypropylene material obtained by a method as taught herein.

A particular aspect of the present invention provides a highly cross-linked polypropylene material which comprises a plurality of polymer chains formed of a plurality of repeating structural units, wherein the polypropylene material comprises carbon-carbon double bonds at least once in every six structural units and/or carbon-carbon double bonds linking adjacent chains.

The highly cross-linked plasma polypropylene material can have any one or more of the following characteristics: Young's modulus in excess of 1.5 GPa, having a hardness of at least 10 MPa, and a k value of between 1.5 and 2.6.

According to another aspect of the present invention, there is provided a substrate including a layer of highly cross-linked polypropylene material obtained by a method as taught herein.

Another aspect of the present invention provides an integrated circuit including at least one dielectric layer formed of highly cross-linked polypropylene material obtained by a method as taught herein.

The method taught herein can produce a highly cross-linked polypropylene material, for instance in the form of a layer, having a relatively low dielectric constant. Moreover, the three dimensionally cross-links formed in the polypropylene ensure that the material or layer is relatively thermally stable, and further that it exhibits mechanical properties after Ashby, consistent with ceramics. PECVD production of the layer does not rely on solvents or water. The resulting consistency, thermal stability and low dielectric constant of the layer produced by the taught method make it well suited to use as a dielectric layer in the manufacture of integrated circuits. Advantageously, the present invention provides a single process step to create both polypropylene polymer chains and cross-links between them, and does not require an additional curing step in order to provide these cross-links.

At lower pressures, the cross-linked polypropylene can be formed as a continuous layer on a substrate. According to preferred methods, the pressure is selected to be less than 5 Torr in order to produce a continuous layer on the substrate where this is desired. In other preferred methods, particularly where the cross-linked polypropylene is desired as flakes or nano-particles formed in the plasma phase, the pressure is selected to be greater than 5 Torr.

The mechanical stress in the polypropylene layer is typically inversely proportional to pressure, due to the greater energy of the ion bombardment on the substrate. Ion bombardment is an intrinsic part of the plasma formation process that can be controlled by the use of the power coupled into the plasma, the pressure and the electrode configurations among other considerations. Those skilled in the art could perform the ion bombardment via other processes. Amongst other things, this ion bombardment affects the adhesion of the layer to the substrate and the surface energies. In preferred embodiments, therefore, the pressure within the chamber is selected to be greater than 200 mTorr.

The mechanical stress in the cross-linked polypropylene layer is also a function of the power per unit area applied to the plasma electrode. The greater the applied power, the greater the rate of growth of the cross-linked polypropylene layer, but also the greater the mechanical stress in the layer. As such, in preferred embodiments, the applied power per unit area of the plasma electrode is less than 0.25 Watts/cm². More preferably, the applied power per unit area of the electrode is less than 0.1 Watts/cm². The mechanical stress can be lowered further with an applied power per unit area to the electrode.

Preferably, the plasma and bias conditions are arranged to minimise damage to the polypropylene layer as it is formed by controlling ion bombardment of the layer. Thus, the substrate may be electrically grounded to produce the high quality films.

The high degree of three dimensional cross-linking in the polymer material provides a higher melting temperature than conventional polypropylene. This cross linking may extend in all three dimensions of the structure. This allows the cross-linked polypropylene material to be used for a wide range of functions. Moreover, such a polymer material benefits from minimal creep and enhanced mechanical properties.

The integrated circuits provided by a polypropylene layer of the type taught herein are able to operate more effectively than conventional integrated circuits which adopt silicon dioxide as a dielectric layer. This is because the dielectric constant or k value of the cross-linked polypropylene layer taught herein is significantly less than that of silicon dioxide. This reduces the energy stored in the layer and correspondingly reduces interference, thereby allowing faster switching times.

In a further embodiment it is possible to have two or more layer dielectric stack whereupon the said polypropylene layer is combined with or encased within a sandwich structure of standard silicon dioxide or silicon nitride layers.

According to another aspect of the present invention, there is provided a method of producing a highly cross-linked polypropylene material including the steps of: providing a reaction chamber; feeding one or more selected carbon containing gases into said chamber, which gases do not include propylene; striking a plasma in said chamber, said plasma causing said gas or gases to dissociate into a phase including methyl radicals; causing said dissociated phase to nucleate and thereby to create highly cross-linked polypropylene material.

This aspect of the present invention can use any of the preferred features taught herein including those set out in any or each of the dependent claims appended or related to claim 1.

### BRIEF DESCRIPTION OF THE DRAWINGS

Preferred embodiments of the present invention will now be described by way of example only with reference to the accompanying figures, in which:

FIG. 1 illustrates a plasma enhanced chemical vapour deposition apparatus;

FIG. 2A illustrates the Fourier transform infra-red (FTIR) spectrum of a first cross-linked polypropylene material;

FIG. 2B illustrates the FTIR spectrum of a second cross-linked polypropylene material;

FIG. 3 illustrates a structural unit of a polypropylene polymer chains;

FIG. 4A illustrates the effect of annealing upon the FTIR spectrum of the first cross-linked polypropylene material;

FIG. 4B illustrates the effect of annealing upon the FTIR spectrum of the second cross-linked polypropylene material;

FIG. 5 illustrates a capacitor device comprising a cross-linked polypropylene material;

FIG. 6 illustrates the effect of annealing upon the k value of a cross-linked polypropylene material;

FIG. 7 illustrates an integrated circuit comprising a cross-linked polypropylene material; and

FIG. 8 illustrates an alternative integrated circuit comprising a cross-linked polypropylene material.

### DETAILED DESCRIPTION OF PREFERRED EMBODIMENTS

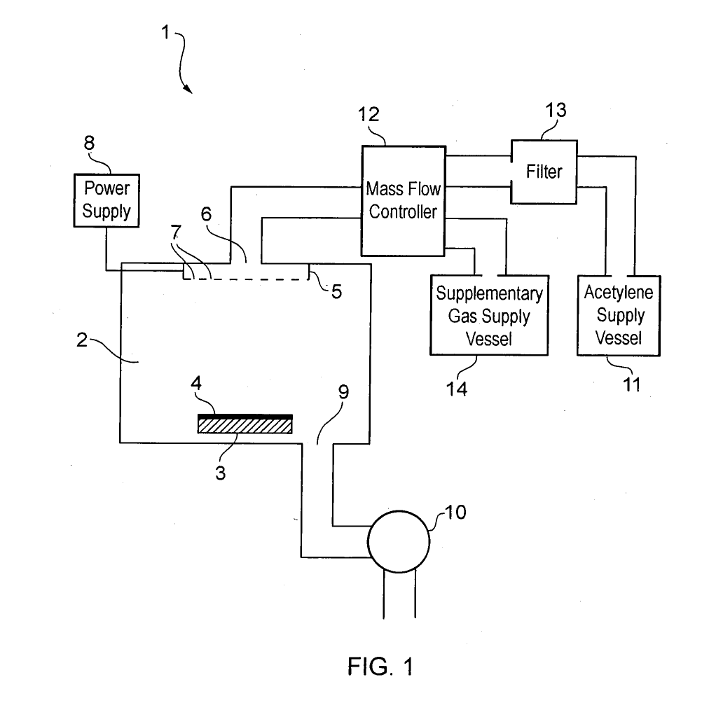

Referring to FIG. 1, an apparatus 1 for plasma enhanced chemical vapour deposition (PECVD) comprises a chamber 2 housing a chuck 3 on which a substrate 4 is mounted. The substrate 4 is, in this embodiment, formed of silicon. However, other materials may be used as a substrate. For example, semiconducting materials, such as germanium, may be used. Alternatively, metals may also be used.

At the top of the chamber 2 is a showerhead 5, which functions as a gas inlet and plasma electrode. More specifically, the showerhead 5 has an inlet 6 though which it receives feedstock gas for use in the PECVD process and a plurality of outlets 7 through which the feedstock gas can pass out of the showerhead 5 and into the chamber 2. The showerhead 5 is preferably metallic. Although the showerhead 5 functions as an electrode in this embodiment, additional or alternative electrode structures may be used.

A power supply 8 is provided that can apply a voltage to the showerhead 5. In preferred embodiments, the power supply 8 provides an alternating current (AC) at a frequency of around 13.56 MHz. Other frequencies may be used, although they are preferably at least 1 Hz. However, in other embodiments the power supply 8 may provide AC at different frequencies or may apply a direct current (DC). Nevertheless, AC is preferred because it negates the risk of charge build up at the electrodes and therefore allows the plasma to be struck at lower power levels. Switched power or linearly controlled bipolar power may be coupled to the plasma to dissociate the gases and minimise ion bombardment. The power provided by the power supply 8 is limited to avoid damage to the deposited layer that would otherwise be caused by ion bombardment.

At the bottom of the chamber 2 is a gas outlet 9 through which gas in the chamber 2 can be evacuated using a vacuum pump 10. In this embodiment, the vacuum pump 10 is a turbo molecular pump. In another embodiment, the vacuum pump 10 is a rotary pump. The vacuum pump 10 is capable of reducing the pressure in the chamber 2 to as low as around 5e-7 Torr.

An acetylene (C₂H₂) supply vessel 11 is also provided. Alternative carbon containing gases to acetylene may also be used. The acetylene supply vessel 11 provides acetylene gas into the chamber at a rate controlled by a mass flow controller 12. A filter 13 may be included to filter the supply of acetylene from the acetylene supply vessel 11. A supplementary gas supply vessel 14 is also provided. The supplementary gas supply vessel 14 provides a supplementary gas which is also passed into the chamber through the mass flow controller 12. Further supplementary gas supply vessels (not shown) are provided, if required, again arranged to supply supplementary gases to the mass flow controller 12. The mass flow controller 12 is therefore able to regulate the relative proportions of the acetylene gas and the supplementary gas or gases in the chamber 2. The combination of acetylene gas and supplementary gas or gases which is provided to the chamber 2 is known as the feedstock gas. This feedstock gas may contain a combination of acetylene and acetone.

The supplementary gas in the preferred embodiment is hydrogen, although alternative or additional supplementary gases may be used. The acetylene supply vessel 11 is typically pressurised and includes a porous material. The acetylene gas is stored in liquid acetone (CH₃COCH₃) within the porous material. Acetone is a volatile hydrocarbon and it is often found that the gas supplied by the acetylene supply vessel 11, and is therefore preferably not pure acetylene but a combination of acetylene and acetone. In some embodiments, it is preferred to ensure that the feedstock gas retains at least a proportion of this acetone as it can improve the production of the cross-linked polypropylene material described below.

The mass flow controller 12 in this embodiment is arranged to provide feedstock gas comprising a proportion of acetylene. The proportion of acetylene can take any value according to requirements, but in the preferred embodiment is between 0.1% and 25%. An exemplary feedstock gas comprises 5% acetylene and 95% hydrogen. The hydrogen component may be replaced with an inert gas such as argon or a mixture of inert and reducing gases such as argon and hydrogen. The 5% acetylene may be replaced by a 5% combination of acetylene and acetone.

In order to use the PECVD apparatus 1 to deposit a material on the substrate 4, the chamber 2 is first evacuated by the vacuum pump 10. The feedstock gas is then fed in to the chamber 2 via the mass flow controller 12 from the acetylene supply vessel 11 and the supplementary gas supply vessel 14 or vessels. From this point on, the vacuum pump 10 is used to maintain a constant pressure in the chamber 2. Regulation of this pressure can also be achieved by using an adjustable valve between the chamber and the vacuum pump, or by regulating the flow rate of the gases. In a preferred embodiment, the pressure is regulated to be greater than 200 mTorr. At lower pressures, the energy of ion bombardment on the substrate 4 is higher and may cause damage to the polypropylene layer and, in particular operating conditions further cause plasma instability.

Once the feedstock gas is in the chamber 2, the power supply 8 provides an AC or a DC to the showerhead 5 in order to strike a plasma in the chamber 2. The plasma is then maintained in a steady state and the process of PECVD occurs. As a result, the highly cross-linked polypropylene film is deposited on the substrate. It is possible to provide a heater (not shown) to apply additional heat to the substrate to increase the thermal stability of the cross-linked polypropylene film. In preferred embodiments, the heater is used to apply heat at a temperature of between 100° C. to 1000° C., more preferably between 200° C. to 500° C., and most preferably between 250° C. and 300° C. UV plasma bombardment during this process may be used.

The mechanism by which the cross-linked polypropylene forms, differs according to the pressure in the chamber 2. At pressures above approximately 5 Torr depending upon specific operating conditions, highly cross-linked polypropylene is produced within the plasma and is then deposited on the substrate. At pressures below approximately 5 Torr, the highly cross-linked polypropylene is produced directly on the substrate 4 itself. The difference between these two processes affects the properties of the cross-linked polypropylene film or material.

Above approximately 5 Torr the highly cross-linked polypropylene nucleates in the plasma phase, and comprises a plurality of distinct particles that settle together to form the layer on the substrate 4. As a result, there are regions in the layer that are left empty, taking on whatever atmosphere the layer is placed in. This has a beneficial effect in terms of the effective k-value, as the k-value of air is very low (approximately 1). However, the material nucleated within the plasma phase does not provide a smooth upper surface to facilitate bonding of additional layers. Where necessary, post processing can palanarise the layer to create very smooth surfaces for integration to device structures, or the mixing with suitable epoxies may allow for thin films to be produced.

At pressures below approximately 5 Torr, the cross-linked material nucleates directly on the substrate 4. Its physical properties are different, particularly as it forms a continuous layer on the substrate 4 with a smooth surface.

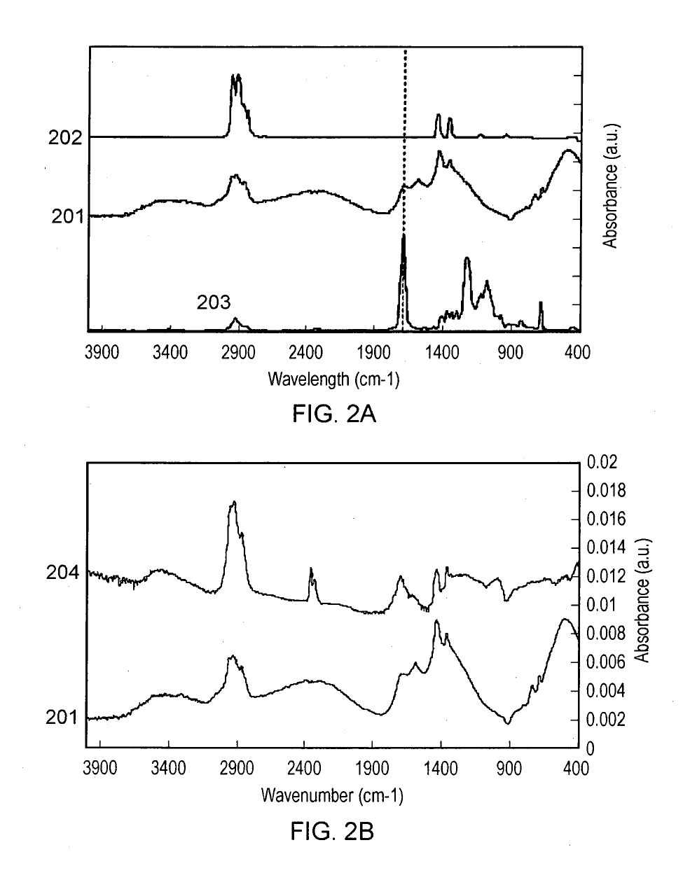

FIGS. 2A and 2B show the spectra 201, 204 of the material nucleated in the plasma phase (henceforth “Material A”) and on the substrate (henceforth “Material B”) obtained from a Fourier transform infra-red (FTIR) spectroscopy apparatus. The spectrum 202 of a control sample of conventionally produced polypropylene is also shown.

It can be seen from FIGS. 2A and 2B that Material A 201 produced at pressures above 5 Torr and Material B 204 deposited at pressures below 5 Torr share a number of absorption peaks with the control sample of polypropylene 202. It can be surmised from this that both Materials A and B have a polypropylene-like backbone structures (that is, they include polypropylene polymer chains). The additional peaks of the spectra 201, 204 of Materials A and B show, however, that they differ from standard polypropylene 202. In particular, the spectra 201, 204 of Materials A and B both show a peak associated with a C═C double bond (an oleophinic bond). This bond is associated with the cross-linking of polymer chains, with increased cross-linking having the macroscopic effect of enhancing the temperature stability of the material, and also providing certain mechanical advantages such as low creep and enhanced mechanical integrity.

The energy within the plasma assists in the production of cross-links between the polymer chains. This energy typically includes ultraviolet radiation, although it may be released in other forms. The use of an ultraviolet radiation containing plasma, for example, can effectively provide a combined singular polymer production and curing process step, assisting in the direct production of a cross-linked polypropylene layer with excellent macroscopic properties. The plasma has an ultraviolet component, and preferably also has higher energy plasma species, ions and electrons.

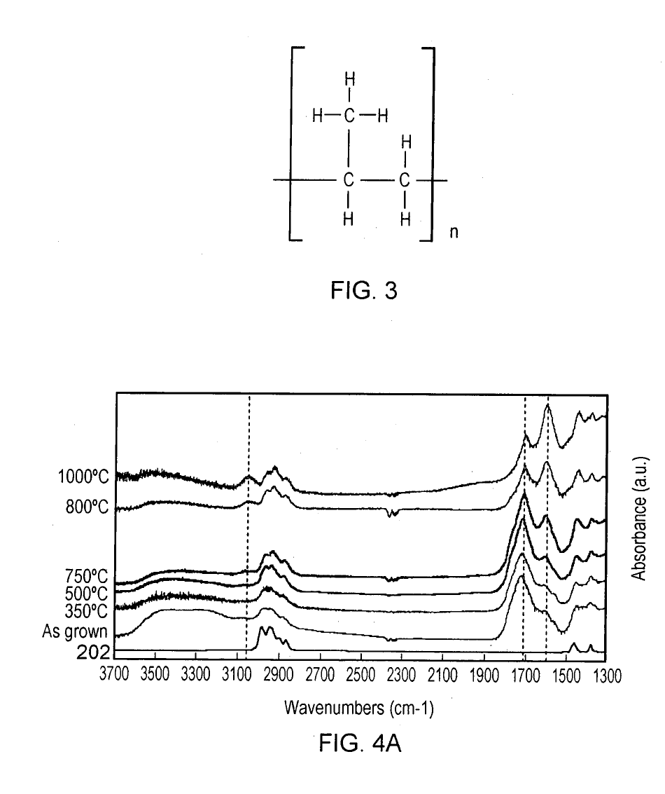

FIG. 3 illustrates the structural unit building block of a conventional polypropylene polymer chain. This unit is repeated to provide a linear polymer chain. The cross-links are those points at which the linear chains are connected to each other.

Analysis of the spectra 201, 204 of Materials A and B in FIGS. 2A and 2B allows estimation of the number of C═C bonds in the material relative to the number of structural units. FIG. 2A also shows the spectrum 203 of polyester, which is used to estimate the peak cross section of various bonds in the FTIR spectrometer. Having calculated the relative cross section of the bonds, it is possible to estimate the number of C═C bonds per structural unit of Materials A and B by comparing the peak ratio of sp²C—H and C═C bonds in their spectra 201, 204.

Using the above analysis, it is found that Materials A and B exhibit C═C bonds at least once every six units of the polymer chain on average. In preferred embodiments, this ratio can be increased to C═C bonds once in every four units. The C═C bonds are ascribed to cross-linking between the polymer chains. This is a high level of cross-linking in such a polymer chain and provides macroscopic advantages including superior thermal stability and negligible creep.

The single structural unit illustrated in FIG. 3 is known as propylene or, more commonly, propene. The rate of cross-linking therefore defines the number of cross-links as compared to the number of propene units in the chain.

The highly cross-linked polypropylene produced by PECVD methods exhibits greater thermal stability than conventional polypropylene. In particular, while the melting point of conventional polypropylene is around 160° C., the melting point of the highly cross-linked polymer is at least 300° C. In preferred embodiments, the melting point can be increased even further. For example, heating the highly cross-linked polypropylene material during its PECVD synthesis further increases its melting point, as does subsequent annealing. A combination of UV plasma bombardment and annealing may be used to enhance the material properties and cross-linking of the polypropylene further. Preferably, the melting point of the highly cross-linked polypropylene is at least 350° C.

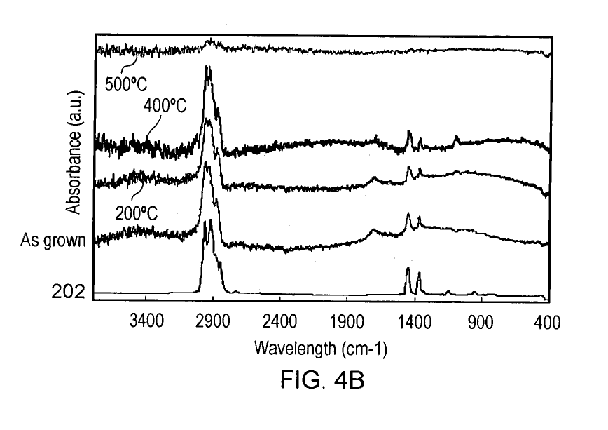

FIGS. 4A and 4B illustrate the thermal stability of Materials A and B respectively. The materials were annealed for ten minutes in a vacuum at a range of temperatures and the FTIR spectra of the annealed result was then analysed. The spectrum 202 of a control sample of conventionally produced polypropylene is also shown in FIGS. 4A and 4B.

The spectra of Material A shown in FIG. 4A illustrate that the material retains its structure even after annealing at temperatures of 1000° C. This is illustrated by the retention of the characteristic absorption bands even at this temperature. Similarly, the spectra of Material B shown in FIG. 4B demonstrate that the material retains its structure at annealing temperatures up to 400° C.

Differences in the relative strengths of the absorption bands in the spectra of Materials A and B are observed as a result of annealing at different temperatures. These can, at least in part, be attributed to changes in the bonds between polymer chains that provide the cross-links. In particular, it has been deduced that annealing causes C═C double bonds to be replaced by aromatic bonds. Aromatic bonds comprise a conjugated ring of carbon atoms and exhibit higher stability. Typically, there are six carbon atoms in the aromatic bond. At annealing temperatures above 750° C., the C═C double bonds are replaced entirely by aromatic bonds.

The stability of the highly cross-linked polypropylene is unusual for polymers at such high temperatures. As a result, it is possible to use this material in a wider variety of conditions without degradation. This is attributed to the high degree of three dimensional cross-linking between the polymer chains.

Although the overall structure of Materials A and B remains intact throughout annealing at high temperatures, as demonstrated in FIGS. 4A and 4B, there may be changes to the macroscopic properties of the material. The annealing process may be used to thermally ‘harden’ the material to limit the macroscopic change that occurs when the material is subsequently heated. This additional annealing step preferably takes place at a temperature of at least 100° C., more preferably at least 200° C., and most preferably at least 300° C.

As well as enhanced thermal stability compared with conventional polypropylene, the highly cross-liked polypropylene has improved mechanical properties, in particular a Young's modulus in excess of 1.5 GPa and a hardness of at least 10 MPa. Further, the highly cross-linked material exhibits negligible creep, enhanced mechanical properties and therefore more closely resembles an industrial ceramic.

This supports the conclusion that the C═C double bonds in the material are the result of highly cross-linked polymer chains in a three dimensional network or matrix which reduces or inhibits relative movement between the chains. The minimal creep observed is as a result of the highly cross-linked polymer chains, which toughen the produced material in comparison to standard polypropylene.

The mechanical and thermal properties of the highly cross-linked polypropylene compared with conventional polypropylene make it better suited to a variety of applications, including as an inter-layer dielectric in the manufacture of integrated circuits. Particularly, the k value of the highly cross-linked material nucleated in the plasma phase is measured as around 1.5, in one embodiment 1.6±0.5, and the k value of the highly cross-liked material formed through direct nucleation on a substrate is measured as around 2.5, in one embodiment 2.24±0.15. These values can be tuned based on the growth conditions.

The k values of the highly cross-linked polypropylene materials are significantly lower than that of silicon dioxide, the substance conventionally used as a dielectric layer in microchips, which is around 3.9. Moreover, the k values of the highly cross-liked materials are further improved by annealing as illustrated in FIG. 6. The annealing step does not appear to reduce the material significantly with a loss of mass, as this would reflect a reduced thickness and a concomitant increase in the k value. To the contrary, and surprisingly, there is observed a decrease in the k value.

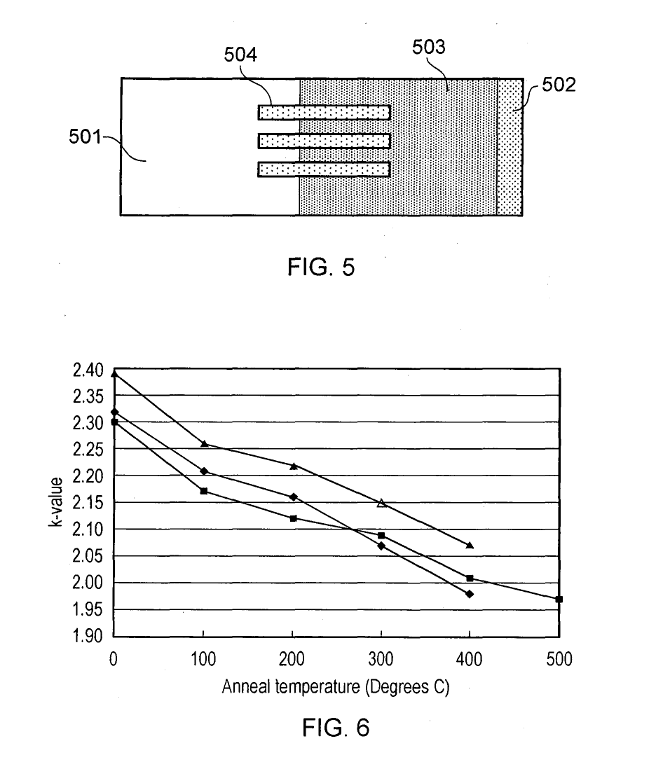

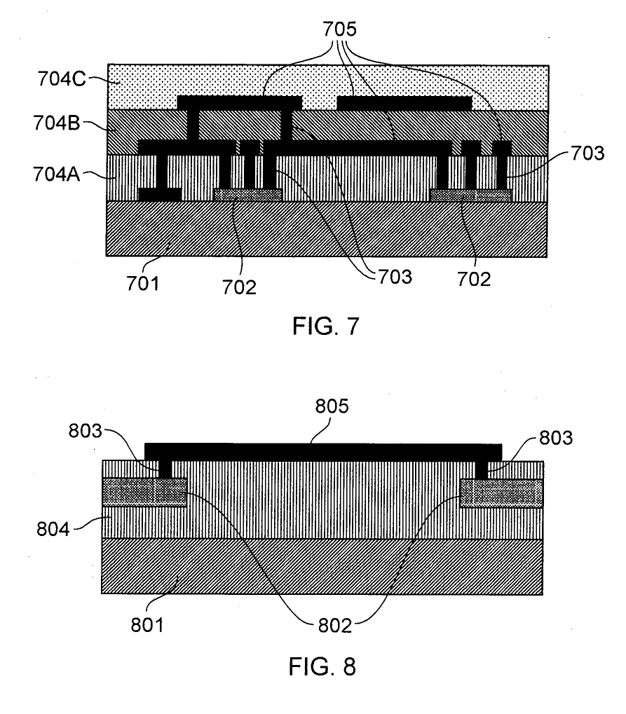

FIG. 5 illustrates a capacitor device comprising a cross-linked polypropylene material. FIG. 7 illustrates an integrated circuit comprising a cross-linked polypropylene material. FIG. 8 illustrates an alternative integrated circuit comprising a cross-linked polypropylene material.

It is to be appreciated that the method and apparatus taught herein could equally use an inductively coupled plasma (ICP), not just RF and DC plasma.

The described embodiments of the invention serve only as examples. Modifications, variations and changes to the described embodiments will occur to those having appropriate skills and knowledge. These modifications, variations and changes may be made without departure from the scope of the invention defined in the claims and its equivalents.

The disclosures in British patent application number 0906680.4, from which this application claims priority, and in the abstract accompanying this application are incorporated herein by reference.

What is claimed is:

1-49. (canceled)

50. A method of producing a highly cross-linked polymer material including the steps of:
providing a reaction chamber;
selecting one or more carbon containing gases from a plurality of carbon containing gases, wherein at least one of the gases is acetylene;
feeding said one or more selected carbon containing gases into said chamber;
feeding acetone into said chamber;
feeding a carrier gas which includes hydrogen into said chamber;
wherein the pressure in said chamber is set to be greater than 200 mTorr and less than 5 Torr;
striking a plasma in said chamber, said plasma causing said gases to dissociate into a phase including methyl radicals;
causing said dissociated phase to nucleate and thereby to create highly cross-linked polymer material.

52. A method as claimed in claim 51, comprising the step of annealing the cross linked polymer material in a vacuum or a controlled gas environment, wherein the controlled gas environment uses one or a composition of inert gases.

53. A method according to claim 52, wherein said annealing step is performed so as to change or reduce the dielectric constant of said nucleated polymer material.

54. A method as claimed in claim 52, wherein annealing is performed at a temperature greater than 100° C.

55. A method as claimed in claim 52, wherein said annealing step is carried out for a period of at least ten minutes.

56. A method as claimed in claim 51, including the step of providing additional heating in the chamber by non-plasma means during the plasma nucleation or synthesis step.

57. A method as claimed in claim 51, including providing in said chamber first and second electrical electrodes, wherein said nucleation step includes applying a potential difference across said first and second electrodes.

58. A method as claimed in claim 57, including providing a substrate disposed on one of said first and second electrodes, wherein said nucleation phase includes applying a potential difference across said first and second electrodes so as to cause said nucleated phase to deposit on said electrode and thereby causing a layer of highly cross-linked polymer material to form on said substrate.

59. A method as claimed in claim 58, wherein the substrate is a part of an electrical or electronic circuit, said deposition of said highly cross-linked polymer material providing an electrically insulating layer on said substrate.

60. A method as claimed in claim 59, wherein said layer of polymer material is applied over a plurality of electrical components or interconnects in the form of an insulating or dielectric interlayer.

61. A method as claimed in claim 59, wherein said layer of polymer material is applied as an interlayer dielectric in an integrated circuit, as an interlayer dielectric of a printed circuit board, as an interlayer dielectric in a capacitor or in any other electrical component including an opto-electronic component or device.

62. A method as claimed in claim 51, including the step of controlling the energy of the plasma by switching of power applied to create the plasma, thereby to minimise damage to nucleated polymer material.

63. A method as claimed in claim 62, wherein switching is effected to achieve a predetermined average plasma power.

64. A method as claimed in claim 51, wherein said polymer material comprises a plurality of polymer chains of repeating structural units, with an average of at least one cross-link per six structural units and/or a plurality of cross-links across adjacent polymer chains.

65. A method as claimed in claim 51, wherein the method produces a highly cross-linked polymer material that exhibits a low dielectric permittivity or k value on a substrate, the method comprising the steps of:
providing a substrate in the chamber, wherein the said substrate is in contact with an electrode;
striking a plasma in the chamber by applying a voltage to a counter electrode inside the chamber, thereby causing a layer of material to form on the substrate;
wherein the plasma has an ultra violet radiation component which enhances the cross-linking of the polymer in three dimensions to give mechanical integrity and thermal stability to the material formed.

66. A highly cross-linked polymer material obtainable by a method as claimed in claim 51.

67. A highly cross-linked polymer material as claimed in claim 66, having a Young's modulus in excess of 1.5 GPa.

68. A highly cross-linked polymer material as claimed in claim 66, having a hardness of at least 10 MPa.

69. A highly cross-linked polymer material as claimed in claim 66, having a k value of between 1.5 and 2.6.

70. An integrated circuit including at least one dielectric layer formed of highly cross-linked polymer material obtainable by a method as claimed in claim 51.

71. An integrated circuit as claimed in claim 70, wherein said layer is disposed between conducting elements of the integrated circuit.
